(19) United States
(12) Patent Application Publication
(10) Pub. No.: US 2009/0296294 A1
(43) Pub. Date: Dec. 3, 2009

(54) ELECTRO-STATIC DISCHARGE PROTECTION DEVICE WITH LOW TEMPERATURE CO-FIRE CERAMIC AND MANUFACTURING METHOD THEREOF

(75) Inventor: Te-Pang Liu, Miaoli (TW)

Correspondence Address: WPAT, PC;INTELLECTUAL PROPERTY ATTORNEYS, 2030 MAIN STREET, SUITE 1300, IRVINE, CA, 92614, US

(73) Assignee: INPAQ TECHNOLOGY CO., LTD., Hsinchu (TW)

(21) Appl. No.: 12/390,903

(22) Filed: Feb. 23, 2009

(30) Foreign Application Priority Data
Jun. 2, 2008 (TW) 097120493

(51) Int. Cl. H02H 9/00; H05K 3/02

(52) U.S. Cl. 361/56; 29/846

(57) ABSTRACT

The present invention relates to an electro-static discharge (ESD) protection device with a low temperature co-fire ceramic (LTCC) and a manufacturing method thereof. The ESD protection device comprises a low temperature co-fire ceramic film having a first patterned conductive electrode material layer and a second patterned conductive electrode material layer therein. The low temperature co-fire ceramic film has at least one via exposing a portion of the first patterned conductive electrode material layer and a portion of the second patterned conductive electrode material layer simultaneously.

### FIELD OF THE INVENTION

The present invention relates to an electro-static discharge (ESD) protection device and a manufacturing method thereof, in particular, to an ESD protection device with a low temperature co-fire ceramic (LTCC) and a manufacturing method thereof.

### DESCRIPTION OF THE PRIOR ART

Over-voltage protection or discharge protection elements have been widely used in circuits of various electronic products for protection or to protect the elements in the electronic products from being damaged by an abnormal voltage or electro-static discharge (ESD), so as to avoid the failure or the shortening of the service life of the electronic products. ESD protection design has become a basic requirement for electronic products.

In order to enable the electronic products to meet the requirements for withstanding ESD, this industry has developed various ESD protection elements, for example, transient voltage suppress diode (TVSD) and multi-layer varistor (MLV), that protect the circuit. Furthermore, in the circuit design, the industry has developed various means for solving the problem of ESD protection design by utilizing, for example, shielding protection, gap discharge, or capacitor charge/discharge. In the Japanese Patent Publication No. JP1995-245878, an over-voltage protection device is disclosed which has a micro gap used for discharging to protect electronic products.

### SUMMARY OF THE INVENTION

The present invention is directed to an ESD protection device. The ESD protection device includes an LTCC film. The LTCC film has a first patterned conductive electrode material layer, a second patterned conductive electrode material layer, and at least one via for exposing a portion of the first patterned conductive electrode material layer and a portion of the second patterned conductive electrode material layer simultaneously.

The present invention is also directed to a manufacturing method for an ESD protection device. The method includes the following steps: providing a first LTCC film having a first patterned conductive electrode material layer; providing a second LTCC film having at least one via; disposing the second LTCC film on the first LTCC film; filling the at least one via with a volatile material; providing a third LTCC film having a second patterned conductive electrode material layer; disposing the third LTCC film on the second LTCC film; and co-firing the first LTCC film, the second LTCC film, and the third LTCC film to volatilize the volatile material, so as to form at least one air gap for exposing a portion of the first patterned conductive electrode material layer and a portion of the second patterned conductive electrode material layer.

According to an embodiment of the present invention, the ESD protection device of the present invention can easily control an electrode spacing so that it falls in the range of 5 μm-30 μm.

According to another embodiment of the present invention, the air gap of the ESD protection device of the present invention exposes one end of a first patterned conductive electrode and one end of a second patterned conductive electrode. A length (L1) of the air gap is greater than a length (L2) of one end of the first patterned conductive electrode, and is greater than a length (not shown) of one end of the second patterned conductive electrode. Meanwhile, a width (W1) of the air gap is greater than a width (W2) of one end of the first patterned conductive electrode, and is greater than a width (not shown) of one end of the second patterned conductive electrode. Such electrodes can discharge in the air gap, so as to protect the electronic products.

According to another embodiment of the present invention, the ESD protection device of the present invention can change a pattern of the first patterned conductive electrode material layer and a pattern of the second patterned conductive electrode material layer, so as to meet different size design requirements.

According to another embodiment of the present invention, the size of the air gap of the ESD protection device is very small, so that a breakdown voltage can be effectively reduced. This simple structure provides a design meeting the ESD low-voltage protection requirement.

To make the features and functions of the present invention more comprehensible, the present invention will be illustrated below in detail with reference to the following embodiments and accompanying drawings.

### BRIEF DESCRIPTION OF THE DRAWINGS

FIGS. 1A and 1B are respectively a top view and a cross-sectional view of a first LTCC film formed according to a first embodiment of the present invention.

FIGS. 2A and 2B are respectively a top view and a side cross-sectional view of a second LTCC film formed according to the first embodiment of the present invention.

FIGS. 3A and 3B are respectively a top view and a side cross-sectional view of the first LTCC film with the second LTCC film disposed thereon after a via is filled with a volatile material according to the first embodiment of the present invention.

FIGS. 4A and 4B are respectively a top view and a side cross-sectional view of the second LTCC film with a third LTCC film disposed thereon according to the first embodiment of the present invention.

FIGS. 5A and 5B are respectively a top view and a side cross-sectional view of a chip of an ESD protection device formed according to the first embodiment of the present invention.

FIGS. 6A and 6B are respectively a top view and a front view of at least one first terminal electrode and at least one second terminal electrode according to the first embodiment of the present invention.

FIGS. 7A and 7B are respectively a top view and a side cross-sectional view of a first LTCC film formed according to a second embodiment of the present invention.

FIGS. 8A and 8B are respectively a top view and a side cross-sectional view of a second LTCC film formed according to the second embodiment of the present invention.

FIGS. 9A and 9B are respectively a top view and a side cross-sectional view of the first LTCC film with the second LTCC film covered thereon after a via is filled by a volatile material according to the second embodiment of the present invention.

FIGS. 10A and 10B are respectively a top view and a side cross-sectional view of the second LTCC film with a third LTCC film disposed thereon according to the second embodiment of the present invention.

FIGS. 11A and 11B are respectively a top view and a side cross-sectional view of a chip of an ESD protection device formed according to the second embodiment of the present invention.

FIGS. 12A and 12B are respectively a top view and a front view of at least one first terminal electrode and at least one second terminal electrode formed according to the second embodiment of the present invention.

FIGS. 13A and 13B are respectively enlarged diagrams of an air gap of an ESD protection device formed according to the present invention.

### DETAILED DESCRIPTION

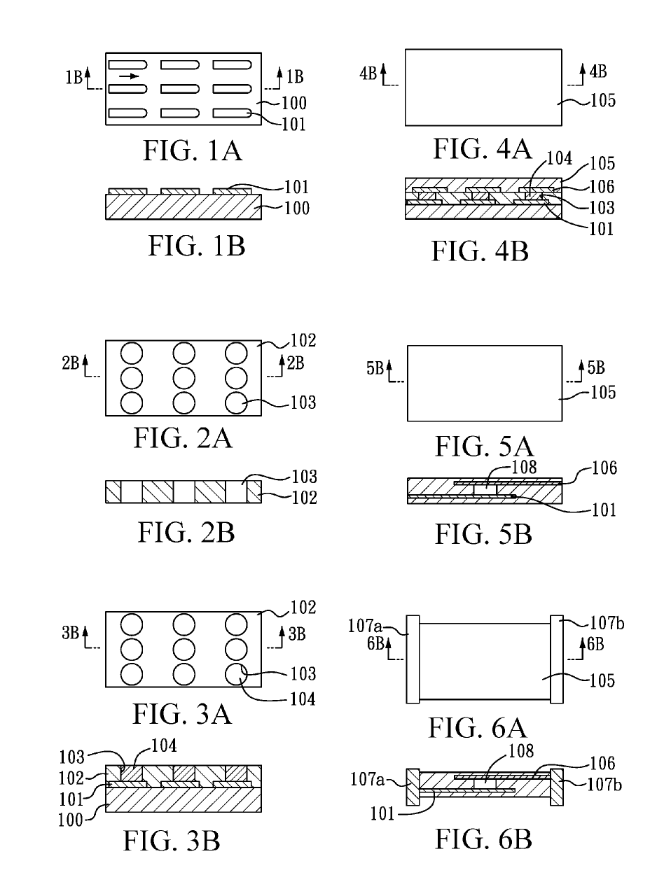

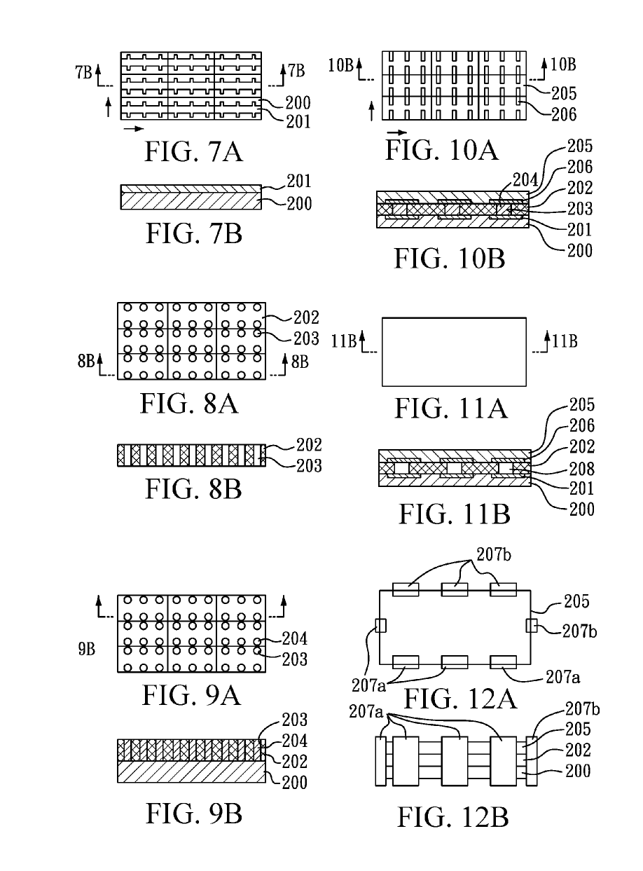

FIGS. 1A to 6B are schematic views of an ESD protection device according to a first embodiment of the present invention. As shown in FIGS. 1A and 1B, the ESD protection device includes a first LTCC film 100. The first LTCC film 100 has a first patterned conductive electrode material layer 101 thereon. The first patterned conductive electrode material layer 101 may be printed on the first LTCC film 100, and the first patterned conductive electrode material layer 101 is disposed in a first direction. As shown in FIGS. 2A and 2B, a second LTCC film 102 is further provided. The second LTCC film 102 has at least one via 103. The at least one via 103 may be formed by perforating the film with a punch machine, and meanwhile, the second LTCC film 102 is disposed on the first LTCC film 100. The first LTCC film 100 and the second LTCC film 102 may be aligned with each other and laminated together. As shown in FIGS. 3A and 3B, the at least one via 103 is filled with a volatile material 104. As shown in FIGS. 4A and 4B, a third LTCC film 105 is provided. The third LTCC film 105 has a second patterned conductive electrode material layer 106 thereon. The second patterned conductive electrode material layer 106 may be printed on the third LTCC film 105. The second patterned conductive electrode material layer 106 is disposed in a second direction that is the same as the first direction. Meanwhile, the third LTCC film 105 is disposed on the second LTCC film 102. The second LTCC film 102 and the third LTCC film 105 may be aligned with each other and laminated together. The first LTCC film 100, the second LTCC film 102, and the third LTCC film 105 may be bonded together tightly by utilizing water pressure. As shown in FIGS. 5A and 5B, a formed film structure is cut into a plurality of chip configurations, and the chips are co-fired after being formed. During the sintering process, the volatile material 104 is fired out, so as to form an air gap 108. The air gap 108 is completely enclosed by the film structure, and a portion of the first patterned conductive electrode material layer 101 and a portion of the second patterned conductive electrode material layer 106 are exposed. As shown in FIGS. 6A and 6B, at least one first terminal electrode 107a for contacting the first patterned conductive electrode material layer 101 and at least one second terminal electrode 107b for contacting the second patterned conductive electrode material layer are formed at two sides of the chip by electroplating. The ESD protection device can be finished by forming at least one tin solder boundary layer (not shown) on the at least one first terminal electrode 107a and on the at least one second terminal electrode 107b.

FIGS. 7A to 12B are schematic views of an ESD protection device structure formed according to a second embodiment of the present invention. As shown in FIGS. 7A and 7B, the ESD protection device includes a first LTCC film 200. The first LTCC film 200 has a first patterned conductive electrode material layer 201 thereon. The first patterned conductive electrode material layer 201 may be printed on the first LTCC film 200, and the first patterned conductive electrode material layer 201 is disposed in a first direction. As shown in FIGS. 8A and 8B, a second LTCC film 202 is further provided. The second LTCC film 202 has at least one via 203. The at least one via 203 may be formed by perforating the film with a punch machine. Meanwhile, the second LTCC film 202 is disposed on the first LTCC film 200. The first LTCC film 200 and the second LTCC film 202 may be aligned with each other and laminated together. As shown in FIGS. 9A and 9B, the at least one via 203 is filled with a volatile material 204. As shown in FIGS. 10A and 10B, a third LTCC film 205 is provided. The third LTCC film 205 has a second patterned conductive electrode material layer 206 thereon. The second patterned conductive electrode material layer 206 may be printed on the third LTCC film 205. The second patterned conductive electrode material layer 206 is disposed in a second direction that is different from the first direction. Meanwhile, the third LTCC film 205 is disposed on the second LTCC film 202. The second LTCC film 202 and the third LTCC film 205 may be aligned with each other and laminated together. The first LTCC film 200, the second LTCC film 202, and the third LTCC film 205 may be bonded together tightly by utilizing water pressure. As shown in FIGS. 11A and 11B, a film structure formed by the above steps is cut into a plurality of chip configurations, and the chips are co-fired after being formed. During the sintering process, the volatile material 204 is fired out, so as to form an air gap 208. The air gap 208 is completely enclosed by the film structure, and a portion of the first patterned conductive electrode material layer 201 and a portion of the second patterned conductive electrode material layer 206 are exposed. As shown in FIGS. 12A and 12B, at least one first terminal electrode 207a for contacting the first patterned conductive electrode material layer 201 and at least one second terminal electrode 207b for contacting the second patterned conductive electrode material layer 206 may be formed at two sides of the chip by electroplating. The ESD protection device can be finished by forming at least one tin solder boundary layer (not shown) on the at least one first terminal electrode 207a and on the at least one second terminal electrode 207b.

The ESD protection device of the present invention can easily control the electrode spacing in the range of 5 μm-30 μm.

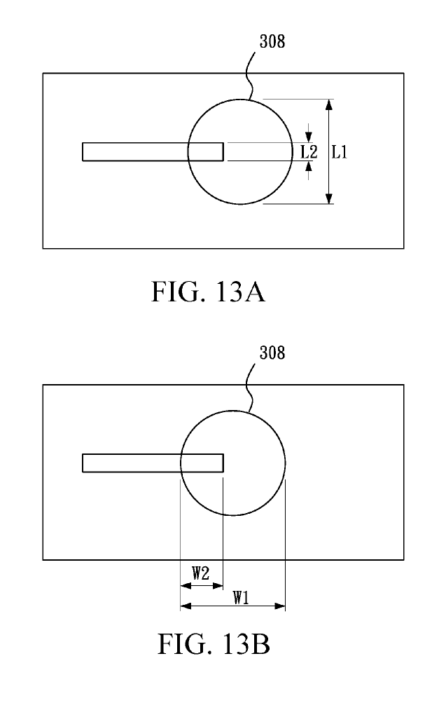

FIGS. 13A and 13B are respectively enlarged diagrams of an air gap of an ESD protection device formed according to the present invention. As shown in FIG. 13A, the air gap (308) exposes one end of a first patterned conductive electrode and one end of a second patterned conductive electrode. A length (L1) of the air gap 308 is greater than a length (L2) of one end of the first patterned conductive electrode and is greater than a length (not shown) of one end of the second patterned conductive electrode. Meanwhile, as shown in FIG. 13B, a width (W1) of the air gap 308 is greater than a width (W2) of one end of the first patterned conductive electrode and is greater than a width (not shown) of one end of the second patterned conductive electrode.

The ESD protection device of the present invention can change a pattern of the first patterned conductive electrode material layer and a pattern of the second patterned conductive electrode material layer, so as to meet different size design requirements.

Meanwhile, the size of the air gap of the ESD protection device formed in the present invention is very small, so that a breakdown voltage can be effectively reduced. This simple structure provides a design meeting the ESD low-voltage protection requirement.

The above embodiments are merely preferred embodiments of the present invention, but do not limit the scope of the present invention. It is intended that the present invention cover modifications and variations of this invention, provided that they fall within the scope of the following claims and their equivalents.

What is claimed is:

1. An electro-static discharge (ESD) protection device, comprising:
a low temperature co-fire ceramic (LTCC) film, including:
a first patterned conductive electrode material layer;
a second patterned conductive electrode material layer, and
at least one via for communicating the first patterned conductive electrode material layer and the second patterned conductive electrode material layer and exposing a portion of the first patterned conductive electrode material layer and a portion of the second patterned conductive electrode material layer.

2. The device according to claim 1, further comprising: at least one first terminal electrode for contacting the first patterned conductive electrode material layer.

3. The device according to claim 1, further comprising: at least one second terminal electrode for contacting the second patterned conductive electrode material layer.

4. The device according to claim 1, wherein the first patterned conductive electrode material layer is disposed in a first direction and the second patterned conductive electrode material layer is disposed in a second direction.

5. The device according to claim 4, wherein the first direction is the same as the second direction.

6. The device according to claim 4, wherein the first direction is different from the second direction.

7. The device according to claim 1, wherein the at least one via exposes a portion of an electrode of the first patterned conductive electrode material layer and a portion of an electrode of the second patterned conductive electrode material layer.

8. The device according to claim 7, wherein the at least one via has a length greater than a length of a portion of an electrode of the first patterned conductive electrode material layer and greater than a length of a portion of an electrode of the second patterned conductive electrode material layer, and has a width greater than a width of a portion of an electrode of the first patterned conductive electrode material layer and greater than a width of a portion of an electrode of the second patterned conductive electrode material layer.

9. A manufacturing method of an ESD protection device, comprising:
providing a first LTCC film having a first patterned conductive electrode material layer thereon;
providing a second LTCC film having at least one via;
disposing the second LTCC film on the first LTCC film;
filling the at least one via with a volatile material;
providing a third LTCC film having a second patterned conductive electrode material layer thereon;
disposing the third LTCC film on the second LTCC film; and
co-firing the first LTCC film, the second LTCC film, and the third LTCC film, to volatilize the volatile material, so as to form at least one air gap, wherein the at least one air gap exposes a portion of the first patterned conductive electrode material layer and a portion of the second patterned conductive electrode material layer.

10. The method according to claim 9, further comprising: forming at least one first terminal electrode for contacting the first patterned conductive electrode material layer.

11. The method according to claim 9, further comprising: forming at least one second terminal electrode for contacting the second patterned conductive electrode material layer.

12. The method according to claim 9, wherein the first patterned conductive electrode material layer is disposed in a first direction and the second patterned conductive electrode material layer is disposed in a second direction.

13. The method according to claim 12, wherein the first direction is the same as the second direction.

14. The method according to claim 12, wherein the first direction is different from the second direction.

15. The method according to claim 9, wherein the portion of the first patterned conductive electrode material layer comprises a portion of an electrode, and the portion of the second patterned conductive electrode material layer comprises a portion of an electrode.

16. The method according to claim 15, wherein the at least one air gap has a length greater than a length of a portion of the electrode of the first patterned conductive electrode material layer and greater than a length of a portion of the electrode of the second patterned conductive electrode material layer, and has a width greater than a width of a portion of the electrode of the first patterned conductive electrode material layer and greater than a width of a portion of the electrode of the second patterned conductive electrode material layer.
